(19) United States
(12) Patent Application Publication
(10) Pub. No.: US 2009/0052479 A1
(43) Pub. Date: Feb. 26, 2009

(54) Saturable absorber structure

(76) Inventor: Arto Salokatve, Tampere (FI)

Correspondence Address: NIXON & VANDERHYE, PC, 901 NORTH GLEBE ROAD, 11TH FLOOR, ARLINGTON, VA, 22203, US

(21) Appl. No.: 11/918,466

(22) PCT Filed: Apr. 21, 2005
(86) PCT No.: PCT/FI2005/000188

§ 371 Date: Feb. 13, 2008

(51) Int. Cl. H01S 3/098; H01L 21/02

(52) U.S. Cl. 372/18; 438/32; 257/E21.002

(57) ABSTRACT

The invention relates to a saturable absorber structure (10) with multiple-layer epitaxial heterostructure absorbers. Typically the structure comprises first absorber layers of a quantum well semiconductor QW-material, which has a nonlinearly on radiation intensity dependent optical absorption; first contacting layers of a first optically transparent semiconductor material against a surface or surfaces of said first absorber layers; and a first Bragg-reflector (23). The first contacting layers have lattice fit or pseudomorphism with said first absorber layers. The absorber layer (13, 13a, 13b) of the QW-material has a thickness (S) of at maximum 60 nm. Further, said first optically transparent semiconductor material of the contacting layer (14, 14a, 14b, 14c) is a reactive R-material, which semiconductor material contains two or more main components, at least one dopant (M2), and at least one metallic alloying element (M1) substituting one of said main components and enhancing the incorporation of said dopant(s). The metallic alloying element has a concentration of at least 50 atomic-% of that main component it substitutes. This way the charge carriers originating in said QW-material of the first absorber layer has a first recombination time at maximum 100 picoseconds determined by recombination of the charge carriers at sites of said dopant(s), thus forming a fast saturable absorber.

### FIELD OF THE INVENTION

The invention relates to saturable absorber structures to be used for attaining passive mode locking of lasers in order to attain generation of ultra-short radiation pulses.

### BACKGROUND OF THE INVENTION

Saturable absorber mirrors are used inside laser resonators for generation of short and ultrashort optical pulses with pulse duration in the picosecond or sub-picosecond range. In particular, saturable absorber mirrors are very useful for the so-called self-starting passive mode locking of lasers, where a periodic train of optical pulses is generated spontaneously by the saturable absorber mirror element. The mechanism of mode locking relies on the non-linear, i.e. intensity dependent, reflectivity of the saturable absorber mirror. The mirror provides large absorption and low reflectivity for low intensity light incident upon it, while for large intensity light the absorption is reduced and reflectance increased; The intensity I where the absorption goes to half of its maximum value is called saturation intensity I_{S} of the saturable absorber. Mathematically the intensity dependent absorption coefficient α(I) can be expressed as

α(I)=α₀/(1+I/I_{S}),

where α₀ is the non-saturated—low intensity—absorption coefficient. Hence, the saturable absorber mirror favors light having high intensity by minimizing losses for such light, and the way the laser resonator achieves this is by locking the relative phases of different longitudinal modes of the laser resonator. Such phase locking exactly produces a periodic train of short optical pulses with high pulse intensity. There are other important requirements aside saturable absorption for the mirror to be useful for passive mode locking. One important property is the recovery time of absorption from the saturated low value back to the unsaturated high value. The recovery time should be sufficiently short for production of picosecond of sub-pico-second pulses. The absorption bandwidth of the saturable absorber should also be sufficiently large for the entire spectrum of the optical pulse to be efficiently absorbed. A third parameter is the non-saturable absorption of the mirror. This absorption the optical intensity cannot bleach, and eventually limits the maximum reflectance exhibited by the mirror or reflector. This part of absorption needs to be kept at minimum.

Most saturable absorber mirrors are based on the Semiconductor Saturable Absorber Mirror (=SESAM). A typical SESAM structure consists of an epitaxially grown Distributed Bragg Reflector (=DBR) on a single crystal semiconductor substrate and an active layer structure including the saturable absorber layers grown on top of the DBR. The DBR reflects the light at the lasing wavelength typically with better than 99% reflectance. The active structure includes single or multiple Quantum Well (=QW) layers that are positioned either at the antinodes or off-antinodes of the standing electromagnetic field within the SESAM structure. By changing the location of the QWs with respect to the standing wave the saturation intensity can be changed. As light is incident on the SESAM, it will experience varying reflectivity depending on its intensity due to saturable absorption in the QW layers. High optical quality QW layers are not suitable for mode-locking since the absorption recovery time is in the range of nanosecond instead of the required picosecond range. Hence, the quality of the QW material must be somehow degraded to facilitate reduction of recovery time, which is determined by the recombination time of the electrons and holes in the QW. Suggested methods to achieve this reduction rely on generation of dislocations, low temperature growth, doping the QW material, and ion implantation of the material. However, all these methods have their drawbacks. Dislocations and low temperature growth tend to make the material interfaces rough and also produce optical scattering, which generates non-saturable loss. Dislocations are not uniformly distributed and the reduction of carrier lifetimes must also be accompanied by relatively slow diffusion of carriers from dislocation free areas into the dislocations acting as recombination centers, whereupon passive mode-locking with picosecond or sub-picosecond pulses cannot be initiated at least in the case of fiber lasers. Furthermore, it is known in the art that the low-temperature growth itself produces e.g. arsenic precipitates reducing carrier lifetime, but unfortunately, said precipitates induce non-saturable losses and raise issues for device robustness and lifetime. Ion implantation degrades the structural quality of the saturable absorber layers and also the DBR layers in the mirror by causing intermixing of the layers. This degradation translates to reduction of optical quality of the structure and generates possible non-saturable loss. Furthermore, implantation is a rather expensive ex-situ process.

Due to the large number of semiconductor layers, the growth of a SESAM structure takes several hours, and a careful control on the layer thicknesses is required due to limited refractive index difference between the semiconductor DBR layers. Since the DBR mirror is grown first on the substrate, the substrate is usually left on the sample and it therefore induces large thermal impedance when the SESAM chip is mounted on a heat sink with the substrate facing the beat sink.

Patent publication U.S. Pat. No. 4,860,296 discloses a controlled laser having an optical resonator, a laser gain medium placed inside the optical resonator, the laser gain medium being capable of emitting light and of lasing with the light, a multiple layer heterostructure placed inside the optical resonator, and means for varying an optical absorption of the multiple layer heterostructure for the light in order to control an optical gain of the optical resonator, and thereby control lasing of the laser gain medium. Passive mode locking is achieved by the light emitted by the gain medium controlling the optical absorption of the multiple layer heterostructure. Active mode locking and modulation are achieved by controlling the optical absorption of the multiple layer heterostructure by applying an electric field to the multiple layer heterostructure. Control of laser gain by an external light source is achieved by controlling the optical absorption of the multiple layer heterostructure by illuminating it with light from the external light source. An embodiment of the multiple layer heterostructure fabricated as a GaAs-AlGaAs multiple quantum well with a Type I superlattice band structure is a passive mode locker for a semiconductor diode laser. Especially there is defined a semiconductor device comprising a first layers of material having a nonlinear optical absorption at a predetermined optical frequency, whereupon a second layers of material alternated with said first layers, and the spacing of said first layers being an integer multiple of one-half the wavelength of light of said predetermined optical frequency. This means that the saturable absorber formed by multiple layer heterostructure is placed between the end mirrors of the optical resonator structure, but Fabry-Perot etalon is not discussed. The scheme presented to achieve passive mode locking relies on very tight focusing of the laser beam on the sample and diffusion of the photo-generated carriers.

According to patent publication U.S. Pat. No. 5,237,577 saturation intensity and loss of a saturable absorber are substantially independently regulated by positioning the saturable absorber element within a Fabry-Perot etalon defined by first and second reflective elements so that the saturable absorber element responds to light at optical wavelengths in the anti-resonant portion of the Fabry-Perot spectral response, that is, between optical wavelengths corresponding to resonance peaks. The resulting combination of elements is called a Fabry-Perot saturable absorber. Thickness of the saturable absorber element substantially sets the loss of the Fabry-Perot saturable absorber while changes in the reflectivity of the first reflective element onto which the light is incident substantially determines the saturation intensity (degree of nonlinearity) and assists in compensating loss of the saturable absorber element. In one exemplary embodiment, a high reflectivity first reflective element is positioned on the end of the saturable absorber element facing the incident optical radiation while a high reflectivity second reflective element is positioned on the opposite end of the saturable absorber. Dielectric material layers form the first reflective element whereas semiconductor layers form the second reflective element. A plurality of quantum well and barrier layers is employed to form the saturable absorber element. Especially the patent discloses an optical apparatus comprising first and second reflective elements being spaced apart to form a Fabry-Perot etalon therebetween, said Fabry-Perot etalon being characterized by a plurality of optical frequencies each frequency corresponding to a resonant condition, and semiconductor material having a nonlinear optical absorption substantially at a predetermined optical frequency and being positioned between said first and second reflective elements, said predetermined optical frequency being between any two adjacent optical frequencies in said plurality of optical frequencies so that said predetermined optical frequency occurs substantially at an optical frequency corresponding to an anti-resonant condition for said Fabry-Perot etalon.

Patent publication U.S. Pat. No. 5,701,327 suggests that low optical loss and simplified fabrication are achieved by a nonlinear reflector which incorporates one or more semi-conductor quantum wells within an n half-wavelengths strain relief layer (where n is an odd integer greater than zero) that is formed on a standard semiconductor quarter wave stack reflector. Growth of the half-wavelength layer is controlled so that dislocations are formed in sufficient concentration at the interface region to act effectively as non-radiative recombination sources. After saturation, these recombination sources remove carriers in the quantum well before the next round trip of the optical pulse arrives in the laser cavity. The nonlinear reflector is suitable for laser mode-locking at the high wavelengths associated with many currently contemplated telecommunications applications and provides, at such wavelengths, an intensity dependent response that permits it to be used for saturable absorption directly in a main oscillating cavity of a laser. Saturation intensity of the nonlinear reflector and thereby related laser mode-locking properties can be controlled by disposing the quantum well(s) at a particular position within the strain relief layer. Further, the patent describes that good mode-locking and good photoluminescence is obtained from quantum wells grown on such strain relaxed layers, while according to well known principles high photoluminescence intensity inevitably means that radiative carrier lifetime is of the same order as non-radiative lifetime.

Patent publication U.S. Pat. No. 6,252,892 discloses an intracavity resonant Fabry-Perot saturable absorber (R-FPSA) induces mode locking in a laser such as a fiber laser. An optical limiter such as a two photon absorber (TPA) can be used in conjunction with the R-FPSA, so that Q-switching is inhibited, resulting in laser output that is CW mode-locked. By using both an R-FPSA and a TPA, the Q-switched mode-locked behavior of a fiber laser is observed to evolve into CW mode locking. Especially the patent claims e.g. a mode-locked laser, comprising: an optical cavity including a gain medium; a Fabry-Perot etalon within said cavity which is near resonance at the laser frequency; and a saturable absorber having nonlinear absorption characteristics and inducing mode-locked laser pulses, said absorber located within said Fabry- Perot etalon. Further the publication mentions ion implantation as the method of carrier lifetime reduction in the saturable absorber.

Patent publication U.S. Pat. No. 6,538,298 discloses a “low field enhancement” (LFR) semi-conductor saturable absorber device design in which the structure is changed such that it has a resonant condition. Consequently, the field strength is substantially higher in the spacer layer, resulting in smaller saturation fluence and in a higher modulation depth. However, the field in the spacer layer is still lower than the free space field or only moderately enhanced compared to the field in the free space. According to one embodiment, the absorber device is a Semiconductor Saturable Absorber Mirror (SESAM) device. In contrast with SESAMs according to the state of the art, a structure including the absorber and being placed on top of a Bragg reflector is provided, which essentially fulfills a resonance condition whereby a standing electromagnetic wave is present in the structure. In other words, the design is such that the field intensity reaches a local maximum in the vicinity of the device surface. According to the example calculations given in the patent reflectivity modulation 1.4% at most can be achieved in such kind of structures. The publication does not suggest any specific means for carrier lifetime reduction.

According to patent publication U.S. Pat. No. 6,551,850 the non-linear optical material characteristics of a semiconductor material grown at low temperatures can be significantly improved by the following measures: Doping with foreign atoms and/or additional thermal annealing. As an example is said that when GaAs grown at 300° C. is doped with Be to a concentration of 3·10¹⁹ cm⁻³, then the response time is reduced from 480 femtoseconds to 110 femtoseconds, without the absorption modulation being reduced by this or the non-saturable absorption losses being increased. Semiconductor materials, during the production of which at least one of the above measures was implemented, manifest influenceable, in particular short response times as well as simultaneously high absorption modulations and low non-saturable absorption losses. The publication suggests that these materials are eminently suitable for non-linear optical applications, such as optical information processing, optical communication or ultrashort laser pulse physics.

### SUMMARY OF THE INVENTION

It is an object of the invention to attain an improved saturable absorber mirror, which addresses many of those problems associated with conventional saturable absorber mirrors of the prior art, and which is usable in lasers having high gain active media. For passive mode-locking of lasers having a high gain active medium, such as fiber lasers, it is needed a saturable absorber mirror that can produce large contrast between high intensity reflectivity and low intensity reflectivity, i.e. large modulation of reflectivity for passive mode-locking. Preferably said difference between the high and low intensity reflectivities should be at least a few percent, because the cavity losses in high gain lasers are generally quite high. This is the reason why saturable absorber mirrors designed to be used with low gain laser media may not work properly with high gain laser media. A good structural integrity of the saturable absorber mirror structure shall be also achieved thus minimizing nonsaturable losses. Furthermore, an efficient heat sinking of the devices shall be possible, because effective cooling is important for long-lived components, especially mode-locked laser oscillators with high average output powers. Further, it is an object of the invention to attain a method, which enable producing said improved saturable absorber mirror.

According to the first aspect of the invention it is provided a saturable absorber structure with multiple-layer epitaxial heterostructure absorbers, comprising: at least a first absorber layer of a quantum well semiconductor QW-material with two opposite surfaces, said QW-material having a nonlinearly on radiation intensity dependent optical absorption at a predetermined optical frequency range of an electromagnetic radiation fed into said absorber structure in direction normal to said opposite surfaces; at least one first contacting layer of a first optically transparent semiconductor material against a surface or surfaces of said first absorber layer(s), said first contacting layer(s) having a lattice fit or a pseudomorphism with said first absorber layer(s); and a first Bragg-reflector with a plurality of quarter wavelength layers. Said at least one absorber layer of the QW-material has a thickness of at maximum 60 nm; and said first optically transparent semiconductor material of the contacting layer(s) is a reactive R-material, which semiconductor material contains two or more main components, at least one dopant, and at least one metallic alloying element substituting one of said main components and enhancing the incorporation of said dopant(s), said metallic alloying element having a concentration at least 50 atomic-% of that main component it substitutes; whereupon the charge carriers originating in said QW-material of the first absorber layer(s) has a first recombination time at maximum 100 picoseconds determined by recombination of the charge carriers at sites of said dopant(s), thus forming a fast saturable absorber. By this way short charge carrier lifetimes in the saturable absorber layers can be achieved without the need to introduce dislocations or perform ion implantation, both of which would introduce non-saturable losses and broaden the spectral features of the absorber material. Strong confinement of the photo-generated carriers in the absorber layers is achieved due to the generally large band-gap of the surrounding contacting layers of R-material. This minimizes carrier leakage out of the absorber layers and improves the time dynamics of the processes that result in the saturation of absorption.

One may also choose not to place the above-mentioned contacting layers around all absorber layers. In such structures two different kinds absorber layers exist, one with fast recovery time (fast saturable absorber) and the other with slow recovery time (slow saturable absorber). For this purpose it is provided at least a second absorber layer of a quantum well semiconductor QW-material with two opposite surfaces, said QW-material having a nonlinearly on radiation intensity dependent optical absorption at a predetermined optical frequency range of an electromagnetic radiation fed into said absorber structure in direction normal to said opposite surfaces; and at least one second contacting layer of an optically transparent semiconductor material against a surface or surfaces of said second absorber layer(s), said second contacting layer(s) having a lattice fit or a pseudomorphism with said second absorber layer(s), whereupon said optically transparent semiconductor material of the second contacting layer(s) is a neutral N-material, which has a lower concentration of said at least one metallic alloying element and/or a lower concentration of said at least one dopant than said R-material of the first contacting layer(s); whereupon the charge carriers originating in said QW-material of the second absorber layer(s) has a second recombination time longer than 100 picoseconds, thus forming a slow saturable absorber. The unique ability to combine slow and fast saturable absorbers in the same structure enables the optimization of initiation and stabilization of mode locking. Further advantage is that both slow and fast saturable absorber layers can be grown into the same structure by placement of the contacting layers.

The lattice fit or said pseudomorphism between the first contacting layer(s) and the first absorber layer(s) is arranged to be so good that said QW-material of the first absorber layer(s) has a dislocation density at maximum 200×10⁴/cm², or smaller than 10×10⁴/cm², or smaller than 5×10³/cm²: This way the point defects at the inter-faces between the contacting layers and the saturable absorber layers are distributed uniformly, and diffusion distances of carriers to these point defects are therefore minimized. Furthermore, all structural damages are kept negligible, and the heat generated in the non-radiative recombination of carriers is also uniformly distributed, which enhances device lifetime.

These similar or different absorber layers ca be positioned in different ways. The absorber structure comprises at least two absorber layers of the QW-material with contacting layers of the R-material or the optional N-material on one side or on both sides of each of said absorber layers, forming two or more absorber units. In one alternative the absorber units are positioned each at or in the proximity of at least one or each antinodes of the standing wave of said radiation, as shown in FIG. 5. In another alternative the absorber units are positioned in one or more groups, in which the absorber units has smaller distance from each other than the spacing between the successive antinodes, at or in the proximity of at least one or each antinodes of the standing wave of said radiation, as shown in FIG. 6. Further the absorber structure may comprise a spacer layer(s) between each of the absorber layers for attaining proper spacing of the absorbers. The spacer layer(s) is/are an optically transparent semiconductor material, like said N-material or said R-material.

The quantum well semiconductor QW-material according to the invention can e.g. be of the type Ga_{X1}In_{1-X1}As, or Ga_{X1}In_{1-X1}As_{Y1}P_{1-Y1}, or Ga_{X2}In_{1-X1}As_{Y1}N_{1-Y1}, in which materials the mole fraction X1 is smaller than 0.5. Alternatively the quantum well semiconductor QW-material can e.g. be of the type (Al_{X1}Ga_{1-X1})_{Y1}In_{1-Y1}As, in which materials the mole fraction X1 is smaller than 0.5.

In the reactive R-material according to the invention the two or more main components of the R-material are selected from among Gallium, Indium, Arsenic, and Phosphorus. Typical examples for the R-material are e.g. (M1_{R}Ga_{1-R})In_{1-X2}As, (M1_{1-R})Ga_{X2}In_{1-X2}P, (M1_{R}Ga_{1-R})In_{1-X2}As_{Y2}N_{1-Y2}, and M1_{R}As_{1-R}, in which the mole fraction R is higher than 0.6, or higher than 0.7, or higher than 0.8. Especially in the R-material of the first contacting layer(s): the metallic alloying element is a metal of group III other than Gallium and Indium, and the dopant is an element of group VI and/or group VIII. Preferably the metal of group III is aluminum, and the dopant element of group VI or VIII is oxygen and/or-iron and/or chromium and/or nickel.

The first Bragg-reflector and the optional second Bragg-reflector can be made of di-electric materials. This kind of reflectors is easier to manufacture than a semiconductor DBR due to larger refractive index differences achieved with dielectric materials. Typically only a few quarter layer pairs are required to achieve more than 99% reflectivity, especially when an enhancing metal layer, such as gold or silver, is deposited on top of the last dielectric layer. Thus, very large reflectance bandwidth can be achieved.

In a preferred embodiment of the invention the absorber structure, i.e. the Hybrid Saturable Absorber Mirror (=HSAM) chip, is bonded onto the heat sink from the first Bragg-reflector, so that the absorber layers of the quantum well semiconductor QW-material with the contacting layers of the first and/or second optically transparent semiconductor material extend away from said heat sink and said first Bragg-reflector. This way the distance from the absorber layers to the heat sink is of the order of a micrometer, since no thick substrate exists between the heat sink and absorber layers. Hence, the chip has low thermal impedance and can operate with high output powers from the mode-locked laser.

According to the second aspect of the invention it is provided a method for producing a saturable absorber structure with multiple-layer epitaxial heterostructure absorbers, comprising: taking a substrate of a semiconductor material; depositing a Bragg-reflector with a plurality of quarter wavelength layers; epitaxially growing one or more first absorber layers of a quantum well semiconductor QW-material, said QW-material being of a type that has a nonlinearly on radiation intensity dependent optical absorption at a predetermined optical frequency range of an electromagnetic radiation; epitaxially growing one or more first contacting layers of a first optically transparent semiconductor material prior to and/or after said growing of the first absorber layer(s) so that said first contacting layer(s) has a lattice fit or a pseudomorphism with said first absorber layer(s). Further in said method: said epitaxial growing of the first absorber layer(s) of the QW-material is finished when a predetermined thickness at maximum 60 nm is reached; and in said epitaxial growing of the first contacting layer(s) one or several main components are supplied, at least one dopant is supplied, and at least one metallic alloying element is supplied, which element either is an additional component or substitutes one of the several main components, and results in a concentration at least 50% of the substituted atomic fraction, so that a reactive R-material is formed for providing a first recombination time at maximum 100 picoseconds for the charge carriers originating in said QW-material of the first absorber layer(s).

According to the aimed product the method can further comprise epitaxially growing one or more second absorber layers of a quantum well semiconductor QW-material composition, said QW-material being of a type that has a nonlinearly on radiation intensity dependent optical absorption at a predetermined optical frequency range of an electromagnetic radiation; and epitaxially growing one or more second contacting layers of a second optically transparent semiconductor material composition prior to and/or after said growing of the first absorber layer(s) so that said second contacting layer(s).has a lattice fit or a pseudomorphism with said second absorber layer(s), and in said epitaxial growing of the second contacting layer(s) is supplied a lower concentration of said at least one metallic alloying element and/or a lower concentration of said at least one dopant than in said first contacting layer(s); whereupon a second recombination time longer than 100 picoseconds is provided for the charge carriers originating in said QW-material of the second absorber layer(s).

Spacer layer or layers prior to or after epitaxial growth of each first and second absorber layer(s), or prior to or after epitaxial growth of each first and second contacting layers are also grown as needed. The first Bragg-reflector with a plurality of quarter wavelength layers is deposited after said epitaxial growing of the first and second absorber layer(s) and the first and second contacting layer(s) and the spacer layer(s) preferably using one or more appropriate dielectric materials.

According to the product in question the saturable absorber structure can be adhered to a heat sink at an end surface of the structure, and especially on top side of said first Bragg-reflector, as shown in FIGS. 1, 4, 5, 6 and 7D. Further, at least said semi-conductor substrate can be selectively removed while maintaining said first and second absorber layer(s) and said first and second contacting layers. A second Bragg-reflector with a plurality of quarter wavelength layers may be deposited on top of said first and second absorber layer(s) and said first and second contacting layers, in position where said semiconductor substrate was removed. This way a Fabry-Perot etalon can be attained.

Especially for attaining said reactive R-material of the first contacting layer(s) the method further comprises: feeding additional gas or gases towards the latest epitaxially grown layer so that component(s) thereof is/are transferred as said at least one additional metallic alloying element and/or as said at least one dopant into said layer, thereby forming said reactive R-material; and/or allowing component(s) of gas or gases present against the latest epitaxially grown first contacting layer(s) of said R-material to be transferred as said at least one dopant onto said layer(s).

### BRIEF DESCRIPTION OF THE DRAWINGS

The foregoing summary, and the following detailed description of the preferred embodiments of the present invention, will be better understood when read in conjunction with the accompanying drawings, in which:

FIG. 1 represents the first and most simple exemplary embodiment of the saturable absorber structure according to the invention, in a section parallel with the direction of the radiation. Here the absorber structure has only one absorber layer of a quantum well semiconductor QW-material and one contacting layer of a reactive R-material.

FIG. 2 represents the second exemplary embodiment of the saturable absorber structure according to the invention, in a section parallel with the direction of the radiation. Here the absorber structure has two absorber layers of a quantum well semiconductor QW-material and three contacting layers of a charge carrier reactive R-material, whereupon every surface of the absorber layers are in contact with the reactive R-material. Contacting layers act as the spacer layers, too.

FIG. 3 represents the third exemplary embodiment of the saturable absorber structure according to the invention, in a section parallel with the direction of the radiation. Here the absorber structure has two absorber layers of a quantum well semi-conductor QW-material and two contacting layers of a charge carrier reactive R-material, whereupon one surface of the absorber layers is in contact with the reactive R-material, and the other opposite surface of the absorber layers is against the spacer layers that are of a neutral N-material.

FIG. 4 represents the fourth exemplary embodiment of the saturable absorber structure according to the invention, in a section parallel with the direction of the radiation. Here the absorber structure has two absorber layers of a quantum well semi-conductor conductor QW-material and two contacting layers of a charge carrier reactive R-material, whereupon both surfaces of one of the absorber layers are in contact with the reactive R-material, and both surfaces of another of the absorber layers is against the spacer layers that are of a neutral N-material.

FIG. 5 represents part of a Fabry-Perot etalon with a plurality of saturable absorbers according to the invention, whereupon the saturable absorbers are positioned so that at or in the proximity of each antinode of the standing wave of the electromagnetic radiation there is one saturable absorber, in the same view as FIGS. 1 to 4. Here the saturable absorbers can be similar or different as compared to each other, i.e. one or some of the can be fast according to the invention, and one or some can be slow. For this Fabry-Perot etalon the semiconductor substrate is removed, like the embodiments of FIG. 1 to FIG. 4, and the etalon is attached on a heat sink. This way high-energy laser pulses can be handled.

FIG. 6 represents a whole Fabry-Perot etalon with a plurality of saturable absorbers according to the invention, whereupon the saturable absorbers are positioned so that at or in the proximity of each antinode of the standing wave of the electromagnetic radiation there is three saturable absorbers, which can be similar or different as compared to each other, in the same view as FIGS. 1 to 5. The saturable absorbers in a group of absorbers for an antinode can be fast or slow or have various speeds, also different groups of saturable absorbers can deviate from each other. For this Fabry-Perot etalon, too, the semiconductor substrate is removed, like the embodiments of FIG. 1 to FIG. 4, and the etalon is attached on a heat sink.

FIGS. 7A to 7D visualizes schematically a saturable absorber structure according to the invention in some of the manufacturing steps for attaining the most completed structure, in the same view as FIGS. 1 to 6.

FIG. 8 lists the main steps of the manufacturing process for attaining the most completed saturable absorber structure according to the invention. One or more of the last steps can be omitted if needed for a specific application.

### DETAILED DESCRIPTION OF THE PREFERRED EMBODIMENTS

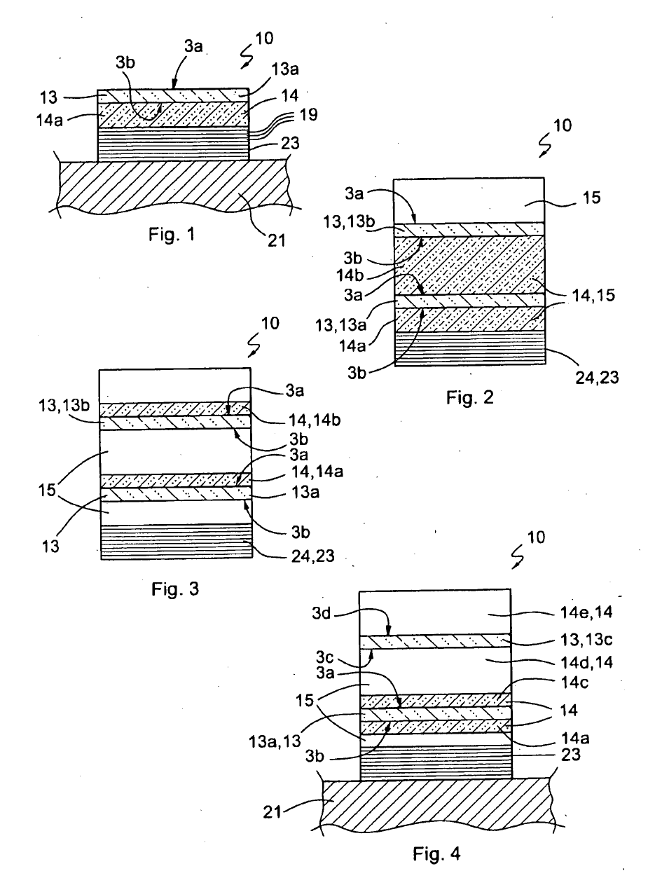

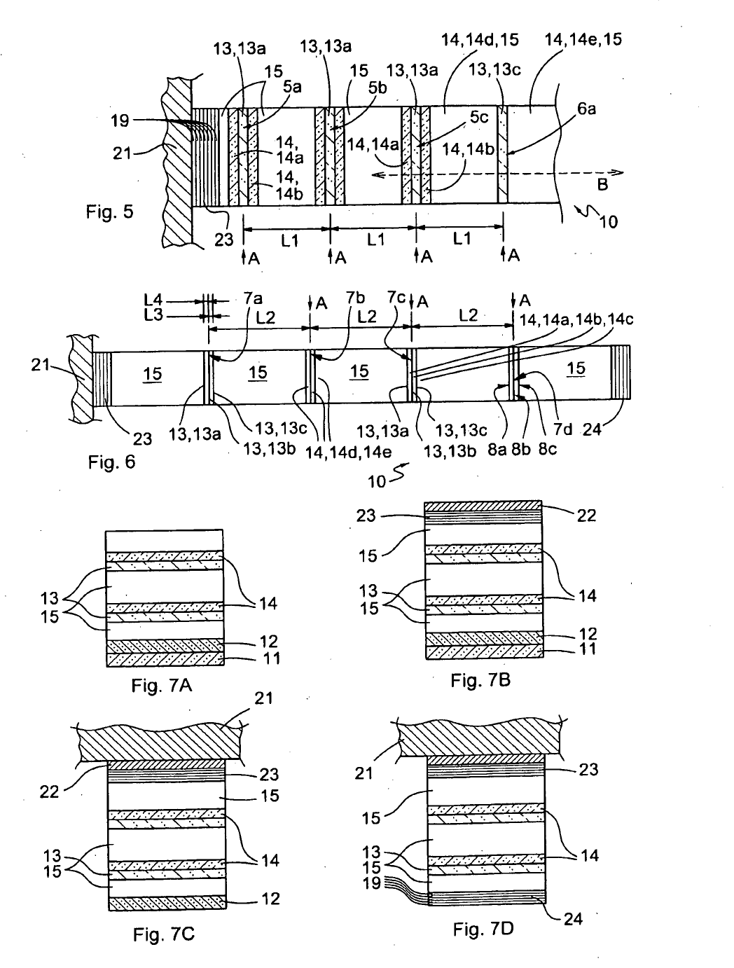

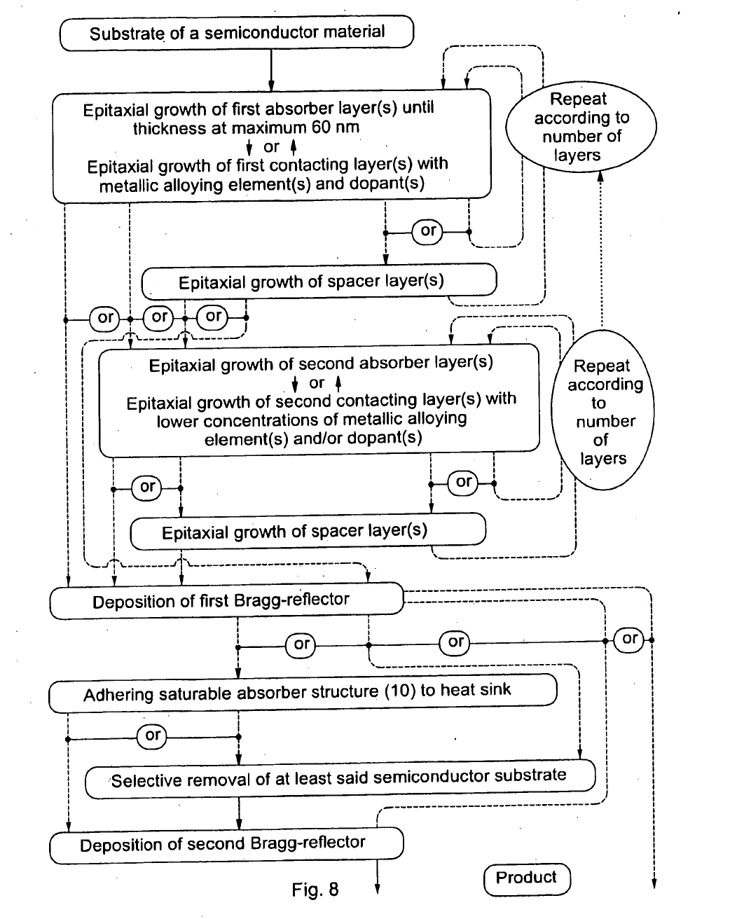

With reference now to the drawings, FIGS. 1 to 4 show some example embodiments for the saturable absorber epitaxial structures—the structures shown can be final or intermediate—grown e.g. by MOCVD or MBE methods known in the art as such, and FIGS. 7A to 7B show examples of the saturable absorber epitaxial structure in some process steps. The structure of FIG. 3 is partly analogous with process of FIGS. 7A to 7B in that the absorber units A, shown in FIGS. 5 and 6, constitutes about one R-material contacting layer against one surface of quantum well QW-material together with neutral N-material spacer layers, which layers and materials are described later in detail. In all cases the absorber structure 10 has been grown on a single crystal semiconductor substrate 11, visible in FIGS. 7A to 7C, whereupon the absorber structure comprises one or a plurality of absorber layers 13, at least one contacting layer 14 adjacent to or in close proximity to each absorber layer 13, and some type of spacer layers 15 between the absorber layers. By close proximity is here meant that charge carriers in the absorber layer 13 are able to interact with the impurities at the closest interface of the contacting layer 14 to achieve the desired reduction in their lifetimes. The reference number 13 is used to identify each absorber layer generally, and more detailed reference numbers 13a, 13b, 13c etc. are used only if distinguishing between separate absorber layer must be made, i.e. each of 13a, 13b, 13c etc. belong to 13. The reference number 14 is used to identify each contacting layer generally, and more detailed reference numbers 14a, 14b, 14c etc. are used only if distinguishing between separate contacting layer must be made, i.e. each of 14a, 14b, 14c etc. belong to 14. The epitaxial structure as such, and the processes for growing such structures are generally known and widely used, and accordingly, they are not described in detail.

The sacrificial layer 12 used during production enables one to detach the actual saturable absorber structure 10 from the substrate 11 at a later processing stage of the saturable absorber structure. For instance, the substrate can be removed by chemically etching it with a first etchant. The composition of the sacrificial layer 12 is chosen such that it is not significantly etched by said first etchant, and therefore the etching will stop when reaching the sacrificial layer 12. Next the sample is subjected to a second etchant, this time selectively etching the sacrificial layer 12, but not significantly etching the rest of the layers 13, 14 15 or any of the subsequent dielectric materials. Alternatively, the sacrificial layer 12 may left as an integral part of the remaining structure. These kinds of etchants and materials for the sacrificial layer are generally known, and are not described in detail. The saturable absorber structure 10 is bonded, if heat sink is used, to a heat sink 21 at the time of etching to provide support for the thin layer structure as shown in FIG. 7C. Alternatively, the sacrificial layer 12 may be left on the structure as an integral part of it. In this case its properties of the sacrificial layer and/or the material of the sacrificial layer, e.g. thickness, refractive index, band gap, have to be taken into account when designing the absorber structure 10.

Preferably the first absorber layers 13, 13a, 13b etc. are quantum wells, i.e. quantum well semiconductor QW-material. The absorber layers have two opposite surfaces 3a, 3b, and a thickness S of at maximum 60 nm, and preferably at maximum 50 nm, or between 1 nm and 40 nm, i.e. from one to few tens of nanometer. The composition of the absorber layers 13 is chosen such that they are absorbent to the laser radiation B, and that the saturation of absorption can be achieved with reasonable saturation intensities. For example, for a 1.06 μm laser radiation the absorber material may be Ga_{X}In_{1-X}As with X≈0.25. QW-materials with nonlinearly on radiation intensity dependent optical absorption, and applicable as materials for absorber layers are generally known, and for the first absorber layers any of the known or possible new materials ca be used. As examples of these applicable QW-materials can be mentioned Ga_{X1}In_{1-X1}As_{Y1}, P_{1-y1}, Gaₓ₁In₁₋ₓ₁As_{Y1}N_{1-Y1} and Gap_{X1}In_{1-X1}As, in which the mole fraction X1 is smaller than 0.5. QW-materials like (Al_{X1}Ga_{1-X1})_{Y1}In_{1-Y1}As, in which the mole fraction X1 is smaller than 0.5, can be alternatively used. Some more detailed examples are listed in the table “Material Examples” below.

The first contacting layers 14 are of a first optically transparent semiconductor material, which more specifically according to the invention contains two or more main components, at least one dopant M2, and at least one metallic alloying element M1 substituting one of said main components and enhancing the incorporation of said dopant(s), said metallic alloying element having a concentration at least 50 atomic-% of that main component it substitutes, which kind of semiconductor material is called a reactive R-material. The mentioned main components of the R-material are nowadays typically Gallium and/or Indium and/or Arsenic and/or Phosphorus, i.e. without the metallic alloying element M1 and without the dopant M2 the composition “R-material” may resemble QW-materials like those mentioned above. But to attain the actual reactive R-material at least one of these main components is replaced partly or totally by a metallic element M1. The first contacting layers 14, 14a, 14b, 14c etc. are grown adjacent to each of the first saturable absorber layers 13, 13a, 13b etc. either at both sides of them—i.e. against both opposite surfaces 3a and 3b—as shown in FIG. 4, and partly in FIG. 2, or at only one side of them—i.e. against one surface 3a or 3b—as shown in FIGS. 1 and 3, and partly in FIG. 2. The contacting layers 14 contain preferably a large fraction of reactive atoms, such as aluminum, in order for them to absorb large numbers of impurity atoms from the vacuum environment. This is why the material of the contacting layers 14 is called reactive R-material. As an example, the first contacting layers 14 may consist of Al_{X}Ga₁₋ₓAs with a large Al fraction X. As an extreme case, first contacting layers 14 for this case may be made of AlAs, whereupon X=1 meaning also that alternative, where one of the main components are totally replaced by the metallic element M1, in this case arsenic is replaced by aluminum. As examples of the applicable R-materials can be mentioned (M1_{R}Ga_{1-R})In_{1-X2}As, (M1_{1-R})Ga_{X2}In_{1-X2}P, (M1_{R}Ga_{1-R})In₁₋ₓ₂As_{Y2}N_{1-Y2} and M1_{R}As_{1-R}, in which the mole fraction R is higher than 0.6, or preferably higher than 0.7, or typically higher than 0.8. The metallic alloying element M1 is a metal of group III of the Periodic table other than Gallium and Indium, and typically the alloying element M1 is aluminum. The alloying element M1 can be introduced in the first contacting layer(s) by the same way as other elements in the epitaxial structure, which is the generally known alternative, and which is not described in detail. Feeding of additional gas or gases towards the latest epitaxially grown layer so can be used not only for introducing the dopant, but also for transferring the at least one additional metallic alloying element M1 into said layer.

According to the invention the reactive R-material contains, not only metallic alloying element M1, but also at least one dopant M2. Definition “dopant” means here, as traditionally, an alloying element, which is present in a concentration at maximum 10⁻⁴ mole fraction. The dopant M2, which is an element or elements of group VI of the Periodic Table, or possibly group VIII of the Periodic Table, can be introduced in the first contacting layer(s) by the same way as other alloying elements in the epitaxial structure, which is the generally known alternative, and which is not described in detail. The element used as the dopant M2 can oxygen and/or iron and/or chromium, but preferably oxygen. Alternatively the growth of the layer(s) may be interrupted at or close to the heterointerfaces between the first contacting layers 14 and the first absorber layers 13 to further enhance the adsorption of impurity atoms, such as oxygen, during the interrupt. The dopant atoms may originate from the gas or gases already present in the atmosphere around the epitaxially grown first contacting layer(s) of said R-material and be transferred as said at least one dopant M2 onto said layer(s). The impurity atoms, i.e. dopant(s), create deep energy levels into the energy band structure and act as effective sink of carriers generated in the first absorber layers 13 forming the saturable absorber. Hence, the carrier lifetime will be drastically reduced thus facilitating the mode-locking generation in the saturable absorber structure 10. The first contacting layers 14 have a further benefit that they are usually of a much wider band-gap than the first absorber layers 13. Therefore, carriers generated within the first absorber layers 13 are effectively confined by the heterobarriers, and are not able to thermally leak out of the absorber layers 13. To further enhance the effect of the first contacting layers 14, gas or gases containing suitable impurity atoms, such as O₂, may be injected or fed through a leak valve during the growth or growth interrupts towards the latest epitaxially grown layer so that component(s) thereof is/are transferred as the dopant(s) M2 into the layer. This ensures that sufficient number of impurity atoms get adsorbed and embedded into the first contacting layer 14 to reach sufficient shortening of the carrier lifetimes, i.e. the first recombination time, in the first absorber layers 13 down to at maximum 100 picoseconds, or shorter than 100 picoseconds. After introducing both the metallic element M1 and the dopant M2 with or without stopping the epitaxial growth for this purpose the first contacting layer(s) of the reactive R-material is formed. The thickness of the contacting layer(s) 14, 14a, 14b . . . can vary considerably, contacting layer(s) may be as thin as a few atoms, or hundreds of nanometers, or even more. It is important that there is either a good lattice fit—especially when the contacting layers are not extremely thin—between each of the absorber layers and the respective contacting layer or layers, or a pseudomorphism—when the contacting layers are very thin—between each of the absorber layers and the respective contacting layer or layers, so that excessive linear and two- and three-dimensional lattice defects are avoided. Accordingly, lattice fit or pseudomorphism respectively between the first contacting layer(s) and the first absorber layer(s) is so good that said QW-material of the first absorber layer(s) has a dislocation density at maximum 200×10⁴/cm², or smaller than 10×10⁴/cm², or smaller than 5×10³/cm².

In the following table is listed some possible QW-materials with nonlinearly on radiation intensity dependent optical absorption, and some R-materials—the dopant is not marked—that can be used together with the mentioned QW-materials. Further, the table tells some optional N-materials, which are discussed later, and the wave-length at which the saturable absorber in question works.

TABLE
Material Examples

| QW-material | R-material | N-material | λ (nm) |
|---|---|---|---|
| Ga_{.82}In_{.18}As | AlAs | Al_{.3}Ga_{.7}As | 0.98 |
| Ga_{.7}In_{.3}As_{.99}N_{.01} | AlAs | Al_{.3}Ga_{.7}As | 1.06 |
| Ga_{.29}In_{.71}As_{.61}P_{.39} | Al_{.48}In_{.52}P | (Al_{.4}Ga_{.6})_{.47}In_{.53}As | 1.3 |
| Ga_{.43}In_{.57}As_{.90}P_{.10} | Al_{.48}In_{.52}P | (Al_{.4}Ga_{.6})_{.47}In_{.53}As | 1.55 |

Dopant D2 is not shown in the table.

In addition to the fast saturable absorbers according to the invention, as disclosed above, and comprising first absorber layer(s) 13, 13a, 13b of a QW-material together with first contacting layers 14, 14a, 14b, 14c of an R-material, the saturable absorber structure 10 according to the invention can comprise further absorber layer(s), i.e. second absorber layer(s) 13, 13c, and second contacting layer(s) 14, 14d, 14e to attain longer recombination times. This is because slow saturable absorbers are preferred for initiation of mode locking, while fast saturable absorbers are preferred for supporting stable short pulse mode-locked operation of the laser. For this purpose there is at least a second absorber layer 13, 13c of a quantum well semiconductor QW-material of the described type with two opposite surfaces 3c, 3d. There is also at least one second contacting layer 14, 14d, 14e of an optically transparent semiconductor material against a surface or surfaces 3c and/or 3d of said second absorber layer(s). Deviating from what is already explained in this text, in this case the optically transparent semiconductor material of the second contacting layer(s) is a neutral N-material. N-material has a lower concentration of the metallic alloying element M1 and/or a lower concentration of the dopant M2 than said R-material of the first contacting layer(s) 14, 14a, 14b, 14c. This way the charge carriers originating in the QW-material of the second absorber layer(s) 13, 13c has a second recombination time longer than 100 picoseconds, thus forming a slow saturable absorber. Hence, the unique capability to combine both slow and fast saturable absorbers in the same structure allows one to optimize the device for both initiation and supporting the mode locking.

The spacer layers 15 separate the at least two absorber layers or the multiple absorber layers from each other, and provide the correct spacing L1 between the different absorber layers 13, 13a, 13b, 13c . . . with their respective contacting layers 14, 14a, 14b, 14c, 14d, 14e . . . placed at or close to different antinodes A of the standing wave pattern, as shown in FIG. 5, or provide the correct spacing L2 between the different groups 7a, 7b, 7c of the absorber layers 13, 13a, 13b, 13c . . . with their respective contacting layers 14, 14a, 14b, 14c, 14d, 14e . . . placed at or close to different antinodes A of the standing wave pattern, as shown in FIG. 6. For example, the groups 7a, 7b, 7c are separated by distances L2 of half optical wavelength when placed at each antinode of the standing wave pattern. The material for the spacer layer(s) 15 can be a neutral N-material that has larger band-gap than that of the QW-material of the saturable absorber layers so that light is not absorbed by the spacer material 15. When the QW-material is Ga_{X1}In_{1-X1}As_{Y1}N_{1-Y1} or Ga_{X1}In_{1-X1}As the neutral N-material may be e.g. GaAs, or Al_{X3}Ga_{1-X3}As, where the mole fraction X3 smaller than 0.5. The N-material for the spacer layers 15 can also be substantially the same material as the contacting layer, i.e. can be same as the reactive R-material, or can be a modified R-material with or without said dopant(s), or with a reduced dopant concentration as compared to said R-material. When the QW-material of the absorber is Ga_{X1}In_{1-X1}As_{Y1}P_{1-Y1}; or (Al_{X1}Ga_{1-X1})_{Y1}In_{1-Y1}As the N-material can be InP, or Ga_{X3}In_{1-X3}As_{Y3}P_{1-Y3}, or (Al_{X3}Ga_{1-X3})_{Y3}In_{1-Y3}As, where the mole fractions X3 and Y3 are such that cause a larger bandgap than in the contacted QW-material. Here too, the N-material for the spacer layers may be substantially the same material as the contacting layer, i.e. can be same as the reactive R-material, or can be modified R-material with or without said dopant(s), or with a reduced dopant concentration as compared to said R-material.

Since at least one mirror or reflector, i.e. the first Bragg-reflector 23 is deposited on the absorber structure, and the saturable absorber structure 10 is typically in connection either with a separate mirror, not shown in the Figures, or with a second Bragg-reflector 24 deposited on absorber structure, so that there is a distance between the first Bragg-reflector 23 and the second Bragg-reflector 24 or the separate mirror, Fabry-Perot etalon is formed. Then a standing wave will exist within the saturable absorber structure when an electromagnetic radiation B with a wavelength λ is fed into the structure 10 in a direction perpendicular to the planes of the layers 13, 14, 15 and reflector(s). For those familiar with the art it is clear that nodes i.e. amplitude maxima, and antinodes A i.e. amplitude minima, form in the standing wave pattern at a given laser wavelength λ. The absorber layers 13 are preferably placed at or close to the antinodes A when minimizing the saturation intensity is preferred, as already explained. One or multiple absorber layers 13, 13a, 13b, 13c . . . can be grouped around each antinode, and one or multiple of such groups may be placed into the structure, one at each antinode or other preferred position close to the antinode. The number and position of the absorber layers 13, 13a, 13b, 13c . . . are determined by the required saturation intensity. It is preferred alternative to have the first and the second Bragg-reflectors 23, 24, which both are formed of a multitude of quarter wavelength layers 19 with two different refractive indices alternating, which are optically transparent semiconductor material, or—as the alternative preferred—optically transparent dielectric material. Bragg-reflectors are generally known, are not described in detail. The first Bragg-reflector 23 may also contain on top of the dielectric stack a metallic high reflectivity layer, which in combination with the di-electric stack enhances the reflectivity and reduces the number of pairs required in the dielectric stack for the target reflectivity for the said reflector. The metallic layer may also serve to facilitate better bonding adhesion via the bonding material 22 to the heat sink 21, as described below.

Further, the saturable absorber structure 10 can comprise a heat sink 21, which is positioned against the first Bragg-reflector 23. In this arrangement the absorber layers 13, 13a, 13b, 13c of the quantum well semiconductor QW-material with said contacting layers 14, 14a, 14b, 14c, 14d, 14e of the first and/or second optically transparent semiconductor material extend away from said heat sink and said first Bragg-reflector. The heat sink 21 comprises a-high thermal conductive material, for example diamond or copper-diamond composite. The saturable absorber structure is attached to the heat sink 21 with a thermally conductive material 22, such as metallic solder.

The saturable absorber structure 10 of FIG. 1 has only one first absorber layer 13, 13a and one first contacting layer 14, 14a, which is against one surface 3b of the absorber layer, between the first absorber layer and-the first Bragg-reflector 23 on top of the heat sink 21. The saturable absorber structure 10 of FIG. 2 has two first absorber layers 13, 13a, 13b and two first contacting layers 14, 14a, 14b, which are against both surfaces 3a, 3b of one absorber layer and one surface 3b of another absorber layer, together with the first Bragg-reflector 23, but without heat sink. The saturable absorber structure 10 of FIG. 3 have also two first absorber layers 13, 13a, 13b and two first contacting layers 14, 14a, 14b, which are against one surface 3a of each another absorber layer, together with the first Bragg-reflector 23. In FIGS. 1 to 3 contacting layer(s) 14 are used in contact or close proximity to the saturable absorber layer(s) 13 to induce shortening of the charge carrier lifetimes by the impurities adsorbed into and especially at the interfaces between the said two layers. The saturable absorber structure 10 of FIG. 4 has one first absorber layer 13, 13a with two first contacting layers 14, 14a, 14c against both surfaces 3a, 3b of the absorber layer, and one second absorber layer 13, 13c with two second contacting layers 14, 14d, 14e against both surfaces 3a, 3b of the absorber layer. In FIG. 4 both fast and slow saturable absorber layers are incorporated, the first absorber layer will act as a fast saturable absorber and the second absorber layer acts as a slow saturable absorber. It shall be understood that, these are simplified Figures to exemplify the principles of the invention, and that in the actual saturable absorbers a plurality of fast absorber layers, optionally a plurality of slow absorber layers, are typically used within the structure to optimize the performance of the structure.

Part of a more complete saturable absorber structure 10 is shown in FIG. 5. Here the structure-comprises a plurality of first absorber layers 13, 13a each with two first contacting layers 14, 14a, 14b against both sides thereof, whereupon a plurality of fast saturable absorber units 5a, 5b, 5c is formed. In this shown alternative each absorber unit 5a, 5b, 5c . . . is formed by one absorber layer together with two contacting layers belonging together so as to attain the fast recombination time at maximum 100 picoseconds. The first absorber layers are positioned at or in proximity of the antinodes A by using spacer layers 15 between every fast absorber unit 5a, 5b, 5c, and—in this case—also between the first Bragg-reflector and one of the absorber units. There is also shown one second absorber layer 13, 13c—in practice several second absorber layers—for which the spacer layers 15 on both sides thereof form the second contacting layers 14, 14d, 14e. This way at least one or a plurality of slow saturable absorber units 6 is formed having a longer recombination time than 100 picoseconds. This or these second absorber layers are also positioned at or in proximity of the antinodes A by using spacer layers 15 between every slow absorber unit 6, and between one above mentioned fast absorber unit 5c and one mentioned slow absorber unit 6.

Another more complete saturable absorber structure 10 is shown in FIG. 6. Here the the first fast absorber unit 8a comprises a first absorber layer 13, 13a and two first contacting layers 14, 14a, 14b on both sides thereof, the second fast absorber unit 8b comprises a first absorber layer 13, 13b and two first contacting layers 14, 14b, 14c on both sides thereof, and the third slow absorber unit 8c comprises a second absorber layer 13, 13b and two second contacting layers 14, 14d, 14e on both sides thereof. There are several groups 7a, 7b, 7c, 7d—in this example four groups—each of which having these absorber units 8a, 8b and 8c proximate to each other. In each group 7a, 7b, 7c, 7d the distances L3, L4 between the absorber units 8a, 8b and 8c, more precisely between the absorber layers 13, 13a, 13b, 13c is smaller, typically substantially smaller, than the spacing L1, L2 between the successive antinodes A. By this way again the absorber layers 13, 13a, 13b, 13c are at or in the proximity of at least one or each antinode A of the standing wave of said radiation B. In this embodiment the fast and slow absorber units are in the same groups, i.e. all groups 7a, 7b, 7c, 7d are similar. As can be understood fast absorber units and slow absorber units can be arranged in separate groups, analogous with the embodiment of FIG. 5, so that some of the absorber groups 7a, 7b, 7c, 7d include only fast units and some of the groups 7a, 7b, 7c, 7d include only slow units. Of course the absorber structure 10 may include only fast absorber units in groups to have first absorber layers both at the antinodes A and proximate to antinodes.

During the manufacturing of the saturable absorber structure 10 according to the invention, including the sacrificial layer 12—if utilized—is first epitaxially grown on the single crystal substrate 11. Next the absorber layer(s) 13 together with the contacting layer(s), i.e. at least the first absorber and contacting layers; but also the second absorber and contacting layers, as well as the possible spacing layer(s) are epitaxially grown onto the sacrificial layer 12, or onto the substrate. The steps of epitaxial growing are repeated as many times as is needed to attain the predetermined number of different layers. The structure after these process steps corresponds to that shown in FIG. 7A. Next the first reflector 23 is deposited on the epitaxial structure, followed by a metallization on the first reflector as shown in FIG. 7B. Next the structure is adhered—if that is in accordance with the specification of final use—from the metallized surface onto the heat sink 21 with a material exhibiting good thermal conduction 22, such as metallic solder. The result is shown in FIG. 7C. The substrate 11 is then selectively removed by wet etching, dry etching, chemo-mechanical etching or a combination thereof. The composition of the sacrificial layer 12 is designed so that the chosen etchant does not significantly attack the sacrificial layer 12. Hence, the sacrificial layer 12 is an etch stop layer. The sacrificial layer 12 may then be selectively removed by etching or it can be left as an integral part of the saturable absorber structure 10 if it is transparent to the desired laser wavelength. Finally the optional second Bragg-reflector 24 is deposited to complete the saturable absorber structure 10. It shall be understood that the second reflector 24 may be left out or it may even be replaced by a passivating layer, depending on the required intensity of the standing wave antinodes in the saturable absorber structure 10.

As a short summary. The present invention describes a saturable absorber structure 10, which can also be called as a Hybrid Saturable Absorber Mirror (HSAM). One embodiment of the HSAM consists of a dielectric mirror on top of which the semiconductor saturable absorber structure is located. The fast recovery time of the absorber layers is achieved in situ by the epitaxial growth process using special contacting layers of a reactive R-material against one side or both sides of the absorber layers of a QW-material. Typically the saturable absorber structure comprises at least two absorber layers 13, 13a, 13b of the QW-material and at least two contacting layers 14, 14a, 14b, 14c of the R-material so that at least one R-material is in contact with each of said absorber layers of the QW-material, whereupon the layers 13, 14 of the QW-material and the R-material form a multi-quantum-well structure. On top of the saturable absorber a second dielectric reflector may be placed for controlling the saturation intensity and the group delay properties of the absorber structure, whereupon reduction of the carrier lifetimes to picosecond or sub-picosecond regime is possible without incurring non-saturable losses like scattering and non-saturable saturable absorption, at the same time keeping structural damages negligible, and which would allow the use of large spot sizes on the saturable absorber sample. The dependence of the standing wave intensity on the reflectivity of the first reflector 23 and the second reflector 24 can be calculated by using e.g. the well-known transfer matrix method. For those familiar with the art, it is clear that also the optical thickness of the saturable absorber structure 10 at the laser wavelength is affecting the standing wave intensity at the said wavelength. There are different alternatives for connections between a saturable absorber and a laser. The saturable absorber structure 10 according to invention can be connected using any of the known or new devices, arrangements, and methods applicable to the intended use. Connections between laser and saturable absorber are, accordingly, not described in this text.

1. A saturable absorber structure (10) with multiple-layer epitaxial heterostructure absorbers, comprising:
at least a first absorber layer (13) of a quantum well semiconductor QW-material with two opposite surfaces (3a, 3b), said QW-material having a nonlinearly on radiation intensity dependent optical absorption at a predetermined optical frequency range of an electromagnetic radiation (B) fed into said absorber structure (10) in direction normal to said opposite surfaces;
at least one first contacting layer (14) of a first optically transparent semiconductor material against a surface or surfaces (3a and/or 3b) of said first absorber layer(s), said first contacting layer(s) having a lattice fit or a pseudomorphism with said first absorber layer(s); and
a first Bragg-reflector (23) with a plurality of quarter wavelength layers (19), characterized in that said at least one absorber layer (13, 13a, 13b) of the QW-material has a thickness (S) of at maximum 60 nm; and said first optically transparent semiconductor material of the contacting layer(s) (14, 14a, 14b, 14c) is a reactive R-material, which semiconductor material contains two or more main components, at least one dopant (M2), and at least one metallic alloying element (M1) substituting one of said main components and enhancing the incorporation of said dopant(s), said metallic alloying element having a concentration at least 50 atomic-% of that main component it substitutes; whereupon the charge carriers originating in said QW-material of the first absorber layer(s) (13, 13a, 13b) has a first recombination time at maximum 100 picoseconds determined by recombination of the charge carriers at sites of said dopant(s), thus forming a fast saturable absorber.

2. A saturable absorber structure according to claim I5 characterized in that said lattice fit or said pseudomorphism respectively between the first contacting layer(s) and the first absorber layer(s) is so good that said QW-material of the first absorber layer(s) has a dislocation density at maximum 200χ104/cm2, or smaller than 10χ104/cm2, or smaller than 5×103/cm2.

3. A saturable absorber structure according to claim I 5 characterized in that it comprises at least two said absorber layers (13, 13a, 13b) of the QW-material and at least two said contacting layers (14, 14a, 14b, 14c) of the R-material so that at least one R-material is in contact with each of said absorber layers of the QW-material; and that said layers (13, 14) of the QW-material and the R-material form a multi- quantum-well structure.

4. A saturable absorber structure according to claim 1, characterized in that the content of said at least one dopant is at maximum 10˜4 mole fraction.

5. A saturable absorber structure according to claim 1, characterized in that it further comprises:
at least a second absorber layer (13, 13c) of a quantum well semiconductor QW-material with two opposite surfaces (3c, 3d), said QW-material having a nonlinearly on radiation intensity dependent optical absorption at a predetermined optical frequency range of an electromagnetic radiation (B) fed into said absorber structure (10) in direction normal to said opposite surfaces; and
at least one second contacting layer (14, 14d, 14e) of an optically transparent semiconductor material against a surface or surfaces (3c and/or 3d) of said second absorber layer(s), said second contacting layer(s) having a lattice fit or a pseudomorphism with said second absorber layer(s), whereupon said optically transparent semiconductor material of the second contacting layer(s) (14, 14d, 14e) is a neutral N-material, which has a lower concentration of said at least one metallic alloying element (M1) and/or a lower concentration of said at least one dopant (M2) than said R-material of the first contacting layer(s) (14, 14a, 14b, 14c); whereupon the charge carriers originating in said QW-material of the second absorber layer(s) (13, 13c) has a second recombination time longer than 100 picoseconds, thus forming a slow saturable absorber.

6. A saturable absorber structure according to claim 1, characterized in that:
it comprises at least two absorber layers (13, 13a, 13b, 13c) of the QW-material with contacting layers (14, 14a, 14b, 14c, 14d, 14e) of said R-material or said Immaterial respectively on one side or on both sides of each of said absorber layers, forming two or more absorber units (5a, 5b, 5c . . . ; 6a); and that—said absorber units are positioned each at or in the proximity of at least one or each antinode (A) of the standing wave of said radiation (B).

7. A saturable absorber structure according to claim 1, characterized in that:
it comprises at least two absorber layers (13, 13a, 13b, 13c) of the QW-material with contacting layers (14, 14a, 14b, 14c, 14d, 14e) of said R-material or said Immaterial respectively on one side or on both sides of each of said absorber layers, forming two or more absorber units ( 8a, 8b, 8c . . . ); and that
said absorber units (8a, 8b, 8c) are positioned in one or more groups (7a, 7b, 7c, 7d . . . ), in which the absorber units has smaller distance (L3, L4) from each other than the spacing (L1, L2) between the successive antinodes (A), at or in the proximity of at least one or each antinode (A) of the standing wave of said radiation (B).

8. A saturable absorber structure according to claim 1, characterized in that it further comprises a spacer layer (15) between each of the absorber layers (13, 13a, 13b, 13c), said spacer layer(s) being an optically transparent semiconductor material.

9. A saturable absorber structure according to claim 8, characterized in that said optically transparent semiconductor material of the spacer layer(s) (15) is said N-material or said R-material.

10. A saturable absorber structure according to claim 1, characterized in that: said QW-material is Ga_{X1}In_{1-X1}As, or Ga_{X1}In_{1-X1}As_{Y1}P_{1-Y1}, or Ga_{X1}In_{1-X1}As_{Y1}N_{1-Y1}, whereupon the mole fraction X1 is smaller than 0.5; or said QW-material is (Al_{X1}Ga_{1-X1})_{Y1}In_{1-Y1}As, whereupon the mole fraction X1 is smaller than 0.5

11. A saturable absorber structure according to claim 1, characterized in that said two or more main components of the R-material are selected from among Gallium, Indium, Arsenic, and Phosphorus.

12. A saturable absorber structure according to claim 10, in that said R-material is a composition of (M1_{R}Ga_{1-R})In_{1-X2}As or (M1_{1-R})Ga_{X2}In_{1-X2}P or (M1_{R}Ga_{1-R})In_{1-X2}As_{Y2}N_{1-Y2} or M1_{R}As_{1-R}, in which the mole fraction R is higher than 0.6, or higher than 0.7, or higher than 0.8; and that in said R-material of the first contacting layer(s):
said metallic alloying element (M1) is a metal of group III other than Gallium and Indium, and
said dopant is an element of group VI and/or group VIII.

13. A saturable absorber structure according to claim 12, characterized in that said metal (M1) of group III is aluminum, and said dopant element of group VI or group VIII is oxygen and/or iron and/or chromium and/or nickel.

14. A saturable absorber structure according claim 1, characterized in that:
in case of Ga_{X1}In_{1-X1}As or Ga_{X1}In_{1-X1}As_{Y1}N_{1-X1})_{Y1}y as the QW-material, said N-material is:
GaAs, or
Al_{X3}Ga_{1-X3}As with the mole fraction X3 smaller than 0.5, and/or without said dopant(s), and/or with reduced dopant concentration as compared to said R-material; or
in case of Ga_{X1}In_{1-X1}As_{Y1}P_{1-Y1} or (Al_{X1}Ga_{1-X1})_{Y1}In_{1-Y1} As as the QW-material, said N-material is:
InP, or
Gaₓ₃In_{1-X3}As_{Y3}P_{1-Y3} or (Al_{X3}Ga_{1-X3})_{Y3}In_{1-Y3} As with mole fractions X3 and Y3 resulting in a larger bandgap than in the contacted QW-material, and/or without said dopant(s), and/or with reduced dopant concentration as compared to said R-material.

15. A saturable absorber structure according to claim 1, characterized in that it further comprises a heat sink (21) positioned against said first Bragg-reflector (23), whereupon said absorber layers (13, 13a, 13b, 13c) of the quantum well semiconductor QW-material with said contacting layers (14, 14a, 14b, 14c, 14d, 14e) of the first and/or second optically transparent semiconductor material extend away from said heat sink and said first Bragg-reflector.

16. A saturable absorber structure according to claim 15, characterized in that it further comprises a second Bragg-reflector (24) at a distance from said first Bragg-reflector (23); and that absorber units formed by said absorber layers (13, 13a, 13b, 13c) of the quantum well semiconductor QW-material with said contacting layers (14, 14a, 14b, 14c, 14d, 14e) of the first and/or second optically transparent semiconductor material being between said first and second Bragg-reflector; whereupon it is a Fabry-Perot etalon.

17. A saturable absorber structure according to claim 1, characterized in that said quarter wavelength layers (19) of the Bragg-reflector(s) (23, 24) are optically transparent semiconductor material or optically transparent dielectric material.

18. A method for producing a saturable absorber structure (10) with multiple-layer epitaxial heterostructure absorbers, comprising:
taking a substrate (11) of a semiconductor material;
depositing a Bragg-reflector with a plurality of quarter wavelength layers (19);
epitaxially growing one or more first absorber layers (13) of a quantum well semiconductor QW-material, said QW-material being of a type that has a nonlinearly on radiation intensity dependent optical absorption at a predetermined optical frequency range of an electromagnetic radiation;
epitaxially growing one or more first contacting layers (14) of a first optically transparent semiconductor material prior to and/or after said growing of the first absorber layer(s) so that said first contacting layer(s) has a lattice fit or a pseudomorphism with said first absorber layer(s), characterized in that further in said method:
said epitaxial growing of the first absorber layer(s) (13, 13a, 13b) of the QW—material is finished when a predetermined thickness (S) at maximum 60 nm is reached; and—in said epitaxial growing of the first contacting layer(s) (14, 14a, 14b, 14c) one or several main components are supplied, at least one dopant (M2) is supplied, and at least one metallic alloying element (M1) is supplied, which element either is an additional component or substitutes one of the several main components, and results in a concentration at least 50% of the substituted atomic fraction, so that a reactive R-material is formed for providing a first recombination time at maximum 100 picoseconds for the charge carriers originating in said QW-material of the first absorber layer(s) (13, 13a, 13b).

19. A method according to claim 18 for producing a saturable absorber structure, characterized in that the method further comprises:
epitaxially growing one or more second absorber layers (13, 13c) of a quantum well semiconductor QW-material composition, said QW-material being of a type that has a nonlinearly on radiation intensity dependent optical absorption at a predetermined optical frequency range of an electromagnetic radiation; and—epitaxially growing one or more second contacting layers (14, 14d, 14e) of a second optically transparent semiconductor material composition prior to and/or after said growing of the first absorber layer(s) so that said second contacting layer(s) has a lattice fit or a pseudomorphism with said second absorber layer(s), and in said epitaxial growing of the second contacting layer(s) (14, 14d, 14e) is supplied a lower concentration of said at least one metallic alloying element (M1) and/or a lower concentration of said at least one dopant than in said first contacting layer(s) (14, 14a, 14b, 14c); whereupon a second recombination time longer than 100 picoseconds is provided for the charge carriers originating in said QW-material of the second absorber layer(s) (13, 13c).

20. A method according to claim 1 for producing a saturable absorber structure, characterized in that the method further comprises epitaxial growing a spacer layer (15) prior to or after epitaxial growth of each first and second absorber layer(s) (13, 13a, 13b, 13c), or prior to or after epitaxial growth of each first and second contacting layers (14, 14a, 14b, 14c, 14d, 14e).

21. A method according to claim 18 for producing a saturable absorber structure, characterized in that further in said method a first Bragg-reflector (23) with a plurality of quarter wavelength layers (19) is deposited after said epitaxial growing of the first and second absorber layer(s) (13, 13a, 13b, 13c) and the first and second contacting layer(s) (14, 14a, 14b, 14c) and the spacer layer(s) (15).

22. A method according to claim 21 for producing a saturable absorber structure, characterized in that the method further comprises adhering said saturable absorber structure (10) to a heat sink (21) at an end surface (31) on top of said first Bragg-reflector (23).

23. A method according to claim 21 for producing a saturable absorber structure, characterized in that the method further comprises selectively removing at least said semiconductor substrate (11) while maintaining said first and second absorber layer(s) (13, 13a, 13b, 13c) and said first and second contacting layers (14, 14a, 14b, 14c, 14d, 14e).

24. A method according to claim 23 for producing a saturable absorber structure, characterized in that the method further comprises depositing a second Bragg-reflector (24) with a plurality of quarter wavelength layers (19) on top of said first and second absorber layer(s) (13, 13a, 13b, 13c) and said first and second contacting layers (14, 14a, 14b, 14c, 14d, 14e), in position where said semiconductor substrate (11) was removed.

25. A method according to claim 18 for producing a saturable absorber structure, characterized in that for attaining said reactive R-material of the first contacting layer(s) (14, 14a, 14b, 14c) the method further comprises:
feeding additional gas or gases towards the latest epitaxially grown layer so that component(s) thereof is/are transferred as said at least one additional metallic alloying element (M1) and/or as said at least one dopant (M2) into said layer, thereby forming said reactive R-material; and/or
allowing component(s) of gas or gases present against the latest epitaxially grown first contacting layer(s) of said R-material to be transferred as said at least one dopant (M2) onto said layer(s).

26. A method according to claim 18, characterized in that for said supplying of the main components of the R-material is used at least Arsenic and/or Phosphorus, and optionally Gallium and/or Indium.

27. A method according to claim 18, characterized in that for said supplying of the metallic alloying element (M1) is used Aluminum; and that for said supplying of the dopant (M2) is used Oxygen and/or Iron and/or Chromium.
